(19) United States
(12) Patent Application Publication
(10) Pub. No.: US 2015/0318426 A1
(43) Pub. Date: Nov. 5, 2015

(54) MITIGATION TECHNIQUES FOR PHOTOVOLTAIC (PV) MODULE INSTALLATION SURFACE ABRASION

(71) Applicants: Bryan Cusick, San Pablo, CA (US); Matthew Danning, Oakland, CA (US); Ajay Friesen, El Cerrito, CA (US); Ian Bennett, El Cerrito, CA (US)

(72) Inventors: Bryan Cusick, San Pablo, CA (US); Matthew Danning, Oakland, CA (US); Ajay Friesen, El Cerrito, CA (US); Ian Bennett, El Cerrito, CA (US)

(21) Appl. No.: 14/266,670

(22) Filed: Apr. 30, 2014

(51) Int. Cl. H01L 31/048; H01L 31/042; E04D 13/00

(52) U.S. Cl. CPC H01L 31/0484; E04D 13/00; H02S 20/00

(57) ABSTRACT

Mitigation techniques for photovoltaic (PV) module installation surface abrasion are described. According to one embodiment, a photovoltaic system includes first and second photovoltaic modules, each including a first coupling element (e.g., mounting leg) on a first end and a second coupling element on a second end opposite of the first end. The system also includes a connector assembly including a fastener adapted to engage the first coupling element of the first photovoltaic module with the second coupling element of the second photovoltaic module. The fastener is configured to provide an engagement state that enables movement of the second coupling element of the second photovoltaic module independent of the first photovoltaic module.

### TECHNICAL FIELD

Embodiments of the present disclosure are in the field of renewable energy and, in particular, include mitigation techniques for photovoltaic module installation surface abrasion.

### BACKGROUND

Solar power has long been viewed as an important alternative energy source. To this end, substantial efforts and investments have been made to develop and improve upon solar energy collection technology. In general terms, solar photovoltaic systems (or simply “photovoltaic systems”) employ solar panels made of silicon or other materials (e.g., III-V cells such as GaAs) to convert sunlight into electricity. More particularly, photovoltaic systems typically include a plurality of photovoltaic (PV) modules (or “solar tiles”) interconnected with wiring to one or more appropriate electrical components (e.g., switches, inverters, junction boxes, etc.). The PV module conventionally consists of a PV laminate or panel generally forming an assembly of crystalline or amorphous semiconductor devices electrically interconnected and encapsulated. One or more electrical conductors are carried by the PV laminate through which the solar-generated current is conducted.

Regardless of an exact construction of the PV laminate, most PV applications entail placing an array of PV modules at the installation site in a location where sunlight is readily present. This is especially true for commercial or industrial applications in which a relatively large number of PV modules are desirable for generating substantial amounts of energy, with the rooftop of the commercial building providing a convenient surface at which the PV modules can be placed. As a point of reference, many commercial buildings have large, flat roofs that are inherently conducive to placement of a PV module array, and is the most efficient use of existing space. While rooftop installation is thus highly viable, certain environment constraints must be addressed. For example, the PV laminate is generally flat or planar; thus, if simply “laid” on an otherwise flat rooftop, the PV laminate may not be optimally positioned/oriented to collect a maximum amount of sunlight throughout the day. Instead, it is desirable to tilt the PV laminate at a slight angle relative to the rooftop (e.g., toward the southern sky for northern hemisphere installations, or toward the northern sky for southern hemisphere installations). Further, possible PV module displacement due to wind gusts must be accounted for, especially where the PV laminate is tilted relative to the rooftop as described above.

In light of the above, conventional PV module installation techniques have included physically interconnecting each individual PV module of the module array directly with, or into, the existing rooftop structure. For example, some PV module configurations have included multiple frame members that are physically attached to the rooftop via bolts driven through (or penetrating) the rooftop. While this technique may provide a more rigid attachment of the PV module, it is a time-consuming process and permanently damages the rooftop. Also, because holes are formed into the rooftop, opportunities for water damage arise. More recently, PV module configurations have been devised for commercial, flat rooftop installation sites in which the arrayed PV modules are self-maintained relative to the rooftop in a non-penetrating manner. More particularly, the PV modules are interconnected to one another via a series of separate, auxiliary components. Ballast is mounted to the PV modules, with the ballast and interconnected PV modules serving to collectively offset wind-generated forces.

### BRIEF DESCRIPTION OF THE DRAWINGS

FIG. 1A is an exploded perspective view of a photovoltaic (PV) module assembly, in accordance with embodiments of the present disclosure;

FIG. 1B is a side view of a PV module portion of the assembly of FIG. 1A mounted to an installation surface, in accordance with embodiments of the present disclosure;

FIG. 1C is a perspective view of the PV module assembly of FIG. 1A, in accordance with embodiments of the present disclosure;

FIG. 1D is a side view of a PV module array including the assembly of FIG. 1A, in accordance with embodiments of the present disclosure;

FIG. 1E is a perspective view of a PV module assembly, in accordance with embodiments of the present disclosure;

FIG. 1F is a side view of a PV module portion of the assembly of FIG. 1E, in accordance with embodiments of the present disclosure;

FIG. 2 is a close-up perspective view of PV modules coupled together in a photovoltaic array using a single-bolt connector assembly, in accordance with embodiments of the present disclosure;

FIG. 3 is a close-up perspective view of photovoltaic modules coupled together in a photovoltaic array using a multi-bolt connector assembly, in accordance with embodiments of the present disclosure;

FIG. 4 is an exploded view of a PV module assembly, including a multi-bolt connector assembly, in accordance with embodiment of the present disclosure; and

FIG. 5 is an exploded view of a PV module assembly, including a multi-bolt connector assembly, in accordance with another embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary, or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled.” The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit.” As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Approaches for mitigation of photovoltaic (PV) module installation surface abrasion are described herein. In the following description, numerous specific details are set forth, such as exemplary ballasted PV module designs, in order to provide a thorough understanding of embodiments of the present disclosure. It will be apparent to one skilled in the art that embodiments of the present disclosure may be practiced without these specific details. For example, although some embodiments are described with reference to non-penetrating (and ballasted) PV module arrays, embodiments may also be implemented in PV array installations that are bolted to a rooftop (or in other penetrating PV array installations). In other instances, well-known techniques, such as PV cell fabrication techniques, are not described in detail in order to not unnecessarily obscure embodiments of the present disclosure. Furthermore, it is to be understood that the various embodiments shown in the figures are illustrative representations and are not necessarily drawn to scale.

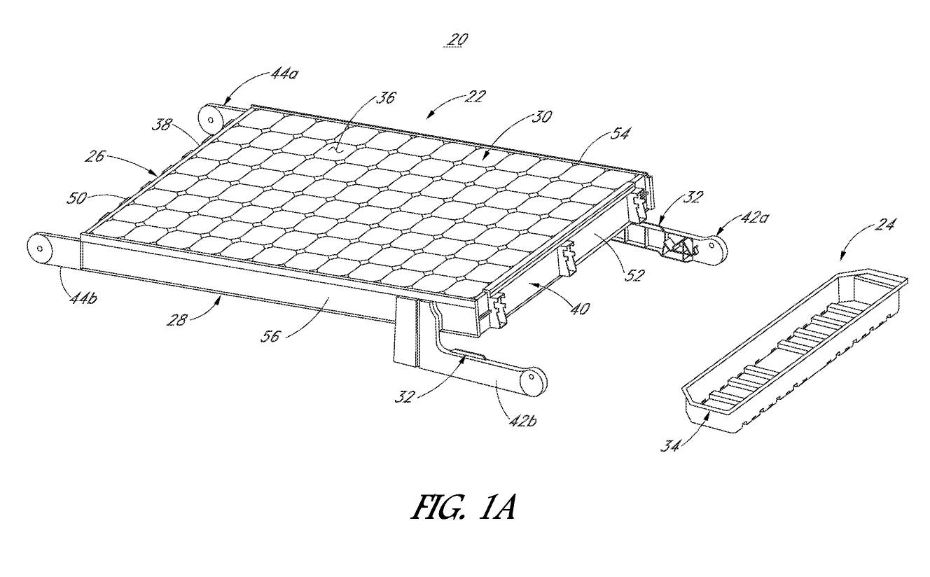

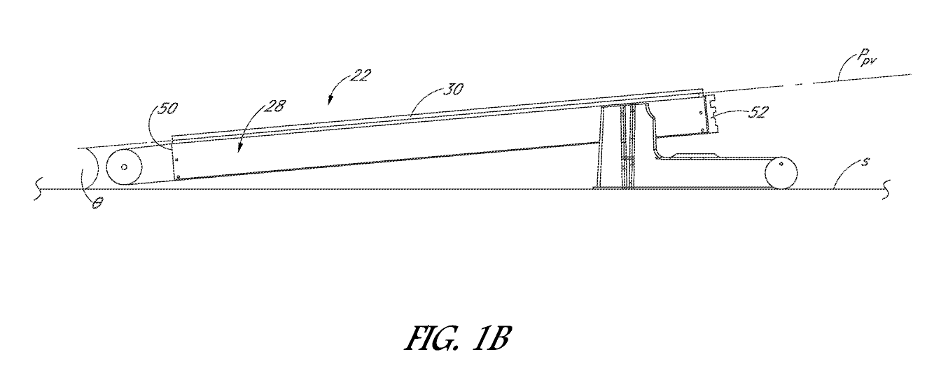

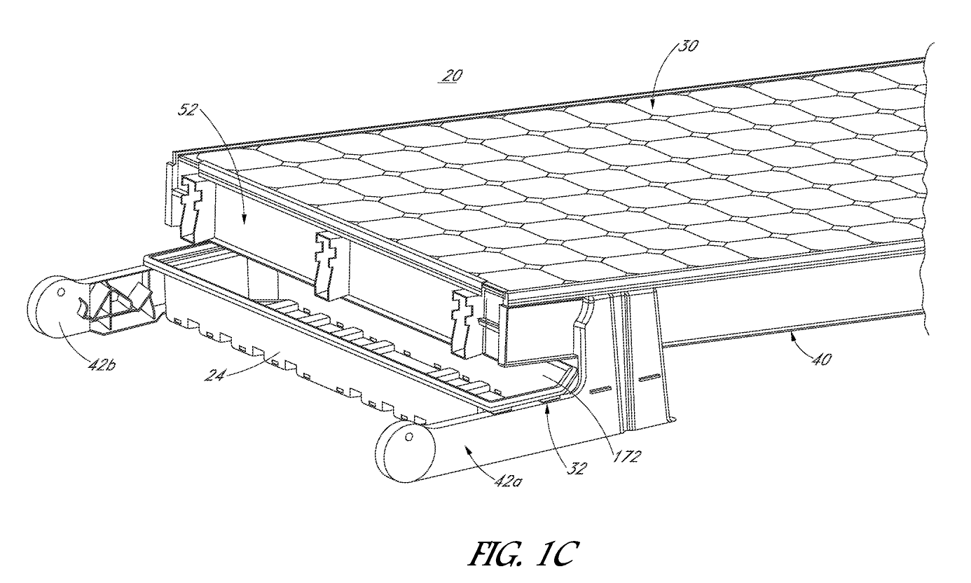

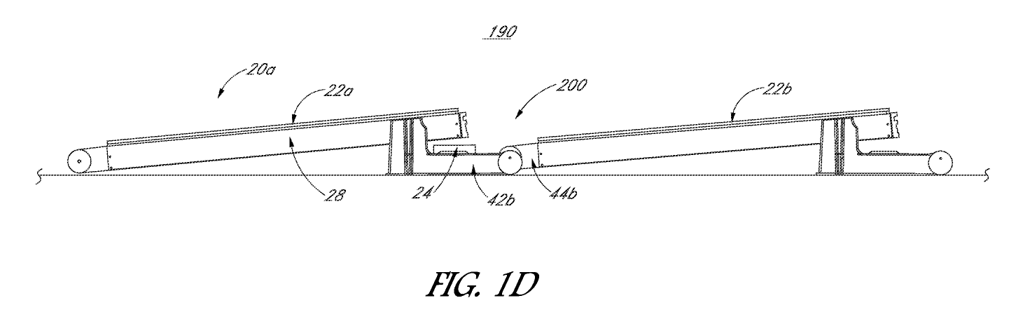

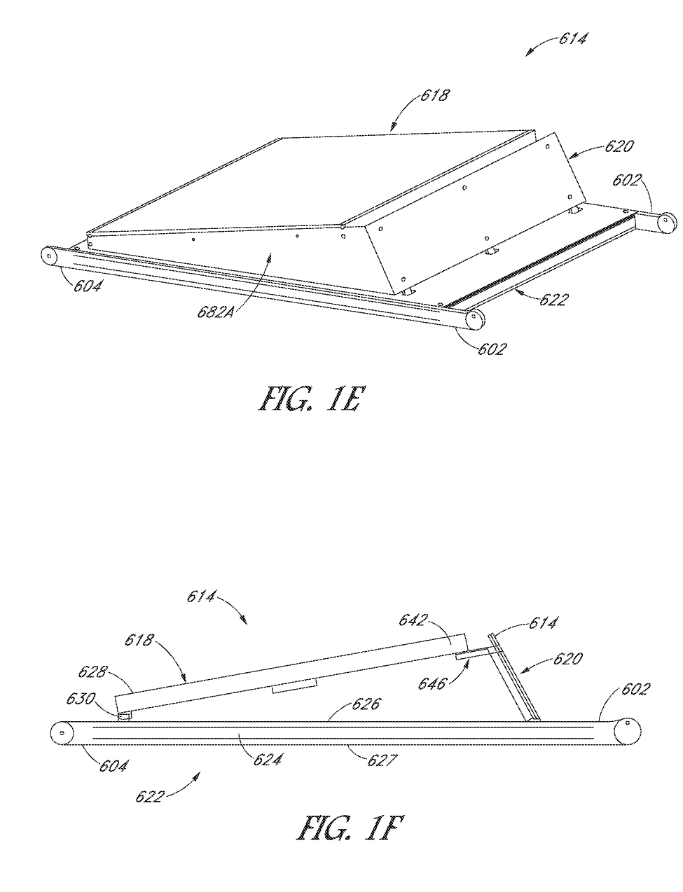

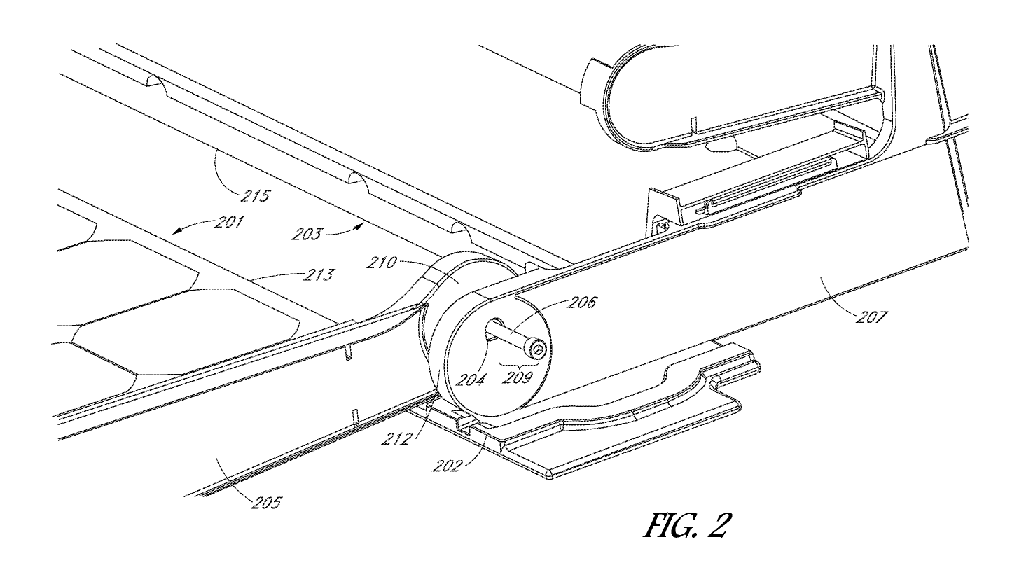

Disclosed herein are PV modules and systems including installation surface abrasion mitigation mechanisms. FIGS. 1A-1D illustrate an example of a photovoltaic module assembly and system, in accordance with embodiments of the disclosure.

FIG. 1A illustrates a perspective view of PV module assembly 20. The PV module assembly 20 includes a PV module 22 and a ballast tray 24. Details on the various components are provided below. In general terms, however, the PV module 22 includes a PV device 26 (referenced generally) and a frame 28. A PV laminate 30 of the PV device 26 is coupled with the frame (e.g., encased by and/or supported over the frame). The frame 28 may provide one or more support faces that effectuate a tilted orientation of the PV laminate 30 relative to an installation surface (e.g., a rooftop).

Further, the frame 28 in the illustrated embodiment provides at least one engagement surface 32 (referenced generally) positioned to interface with the tray 24 upon installation. The tray 24 can be formed from various materials having any desired strength, stiffness, or other property. In some embodiments, the tray 24 is formed of plastic or polymeric material(s). For example, the tray 24 can be a molded polymeric component, such as injection molded PPO/PS (Polyphenylene Oxide co-polymer/polystyrene blend) or PET (Polyethylene Terephthalate), although other polymeric or electrically-insulating materials are also acceptable. With these constructions, use of the optional non-conductive plastic tray 24 as part of the PV module assembly 20 does not require additional grounding components (or related installation procedures). In a related embodiment, the frame 28 similarly can be formed of a plastic or polymeric material(s) to electrically ground the PV module assembly 20. Alternatively, however, one or both of the tray 24 and/or the frame 28 can be partially or entirely formed of metal. In some embodiments, where at least the frame 28 is partially or entirely plastic, features of the present disclosure by which the tray 24 is not physically mounted to the frame 28 (or otherwise does not bear against the frame 28) in the ballasting state may enhance the long-term integrity of the frame 28.

The tray 24 is adapted to contain ballast (not shown), and is removably associated with the PV module 22, and in particular the frame 28. In this regard, the tray 24 and the frame 28 are configurable such that in a ballasting state of the assembly 20 and the tray 24 is at least partially disposed under the PV laminate 30 in a removable manner, and impedes overt movement of the PV module 22 (e.g., upward movement relative to an installation surface) via contact between a stop surface 34 (referenced generally) of the tray 24 and the engagement surface 32 of the frame 28. With this configuration, the PV module assembly 20 is highly useful for non-penetrating, rooftop installations in which ballast for the PV module 22 may or may not be necessary, and where provided, the ballast may impart minimal point loading on the frame 28.

PV module arrays (e.g., ballasted PV module arrays) may experience undesirable movement across the installation surface, resulting in abrasion of the installation surface. According to existing techniques, when many PV modules are bolted together in long rows and columns, the thermal expansion and contraction stacks across the modules, which can cause substantial movement of the PV modules at the perimeter of a ballasted array across the installation surface. The movement of the PV modules at the perimeter of the ballasted array can be especially problematic when the array is installed on a sloped rooftop. During periods of thermal expansion, the force exerted by the expanding array may overcome the friction force between the downhill portion of the array and the installation surface, causing the array to expand towards the downhill slope. Similarly, during periods of contraction, the friction force between the uphill portion of the array and the installation surface may be overcome by forces exerted by the contracting modules. Multiple cycles of expansion and contraction can result in the PV modules “walking” down the installation surface. The movement of the PV module array has the potential to abrade the installation surface, resulting in leaks and other damage to the installation surface.

Additionally, even in PV systems that do not experience significant movement across the installation surface (e.g., PV systems that include an anchoring mechanism that penetrates the installation surface), forces exerted on the parts of the PV system due to thermal expansion and contraction may cause wear and damage to the PV system over time.

According to embodiments of the present disclosure, photovoltaic modules and systems include mechanisms that create greater friction between one end of a given PV module frame and the installation surface than at the opposite end of the PV module frame, and enable movement of the lower friction end of the PV module frame relative to another adjacent PV module to which the PV module is coupled.

For example, in one embodiment, a photovoltaic module includes a photovoltaic laminate and a frame coupled to the photovoltaic laminate. The frame includes a first coupling element on a first end and a second coupling element on a second end opposite the first end of the frame. The first coupling element of the photovoltaic module is adapted to releasably attach the photovoltaic module to an installation surface. The first coupling element is also adapted to releasably couple with a second coupling element of a different photovoltaic module. The first coupling element has a first coupling interface adapted to couple to a connector assembly for engagement with the second coupling element of the different photovoltaic module. The second coupling element of the photovoltaic module has a second coupling interface adapted to couple to the connector assembly. Engagement of the first coupling element of the photovoltaic module with the second coupling element of the different photovoltaic module permits substantial planar movement of the second coupling element of the different photovoltaic module independent of the photovoltaic module.

According to another embodiment, a photovoltaic system includes first and second photovoltaic modules, each including a first coupling element on a first end and a second coupling element on a second end opposite of the first end. The system also includes a connector assembly including a fastener adapted to engage the first coupling element of the first photovoltaic module with the second coupling element of the second photovoltaic module. The fastener is configured to provide an engagement state that enables movement of the second coupling element of the second photovoltaic module independent of the first photovoltaic module.

According to another embodiment, a photovoltaic system includes a PV module. The PV module includes a photovoltaic laminate and a frame coupled with the photovoltaic laminate. The frame includes a first leg at a first end of the frame and a second leg at a second end of the frame opposite to the first end. The first leg is configured to rest on an installation surface, creating friction between the first leg and the installation surface. The second leg includes a hole that at least partially overlaps a hole in a first leg of another photovoltaic module when the photovoltaic module is adjacent to and coupled with the other photovoltaic module on the installation surface. The system also includes a bolt sized to pass through the hole in the second leg of the photovoltaic module and the hole in the first leg of the other photovoltaic module to slidably couple the second leg of the photovoltaic module with the first leg of the other photovoltaic module, creating less friction between the second leg of the PV module and the first leg of the other photovoltaic module than between the first leg of the PV module and the installation surface.

Thus, the PV modules may be installed on a rooftop (or other installation surface) in a way that isolates the PV modules from each other regarding thermal expansion and contraction. Such techniques may maintain wind loading requirements and secure the modules to the installation surface, while enabling the coupled ends of the PV modules to move relative to each other. Embodiments may thus prevent the thermal expansion and contraction from stacking across multiple modules, and therefore prevent abrasion to the installation surface from PV module movement. Even in PV arrays that are attached to the installation surface via a penetrating mechanism (and therefore unlikely to experience significant PV module movement across the installation surface), embodiments may relieve stress on the parts of the PV module array caused by thermal contraction and expansion. Thus, embodiments may minimize damage to PV module arrays due to thermal expansion and contraction, and may increase the longevity of the parts of the PV module array.

Referring again to the Figures, the PV module assembly 20 can assume a variety of forms that may or may not be implicated by FIG. 1A. For example, the PV device 26, including the PV laminate 30, can have any form currently known or in the future developed that is otherwise appropriate for use as a solar photovoltaic device. In general terms, the PV laminate 30 consists of an array of photovoltaic cells. A glass laminate may be placed over the photovoltaic cells for protection. In some embodiments, the photovoltaic cells advantageously include backside-contact cells, such as those of the type available from SunPower Corp., of San Jose, Calif. As a point of reference, in backside-contact cells, wirings leading to external electrical circuits are coupled on the backside of the cell (i.e., the side facing away from the sun upon installation) for increased area for solar collection. Other types of photovoltaic cells may also be used without detracting from the merits of the present disclosure. For example, the photovoltaic cells can incorporate thin film technology, such as silicon thin films, non-silicon devices (e.g., III-V cells including GaAs), etc. Thus, while not shown in the figures, in some embodiments, the PV device 26 can include one or more components in addition to the PV laminate 30, such as wiring or other electrical components.

Regardless of an exact construction, the PV laminate 30 can be described as defining a front face 36 and a perimeter 38 (referenced generally in FIG. 1A). As a point of reference, additional components (where provided) of the PV device 26 are conventionally located at or along a back face of the PV laminate 30, with the back face being hidden in the view of FIG. 1A.

According to the illustrated embodiment, the frame 28 is coupled with the PV laminate 30. The frame 28 generally includes framework 40 adapted to encompass the perimeter 38 of the PV laminate 30, along with coupling elements 42a, 42b extending from the framework 40. For example, in the embodiment illustrated in FIG. 1A, the frame 28 includes legs (alternatively referred to as “arms”) 42a, 42b extending away from the PV laminate 30. Additional coupling elements 44a, 44b on the side of the frame 28 opposite to the coupling elements 42a, 42b may also be in the form of legs, as illustrated in FIG. 1A. Thus, the illustrated frame 28 includes the first coupling element (e.g., coupling elements 42a and/or 42b) on the first end and the second coupling element (e.g., coupling elements 44a and/or 44b) on the second end opposite the first end of the frame 28.

As described below, the coupling elements 42a, 42b can include features for coupling with one or more of an installation surface, an adjacent PV module, and/or a ballast tray. For example, according to one embodiment, the first coupling element(s) 42a, 42b of the photovoltaic module are adapted to releasably attach the photovoltaic module 22 to an installation surface. In the illustrated embodiment, the coupling element(s) 42a, 42b incorporate one or more features that facilitate desired interface with the tray 24 upon final installation, such as providing the engagement surface 32. In more general terms, however, the frame 28 is configured to facilitate arrangement of the PV laminate 30 at a tilted or sloped orientation relative to an installation surface. For example, in one embodiment the PV module is mounted on a substantially flat surface (e.g., maximum pitch of 2:12), such as a rooftop. However, embodiments described herein may be used on other installation surfaces having greater pitch (e.g., a surface having a pitch greater than 2:12) or lesser pitch (e.g., a slope of 0), wherein the maximum pitch may be based on the mechanism used to secure the PV array to the installation surface. For example, a ballasted array that is not bolted into the installation surface may be limited to lower pitch installation surfaces, whereas a PV array attached to an installation surface using a penetrating means may be mounted to a higher pitch installation surface. Referring again to FIG. 1A, the framework 40 can be described as including or providing a leading side or leading frame member 50, a trailing side or trailing frame member 52, a first side or first side frame member 54, and second side or second side frame member 56.

With these conventions in mind, FIG. 1B provides a simplified illustration of the PV module 22 relative to a flat, horizontal surface S. Though hidden in the view of FIG. 1B, a location of the PV laminate 30 is generally indicated, as is a plane P_{PV} of the PV laminate 30 that is otherwise established by the front face 36 (FIG. 1A). Relative to the arrangement of FIG. 1B, the frame 28 supports the PV laminate 30 relative to the flat surface S at a slope or tilt angle θ. The tilt angle θ can otherwise be defined as an included angle formed between the PV laminate plane P_{PV} and a plane of the flat surface S. In some embodiments, the frame 28 is configured to support the PV laminate 30 at a tilt angle θ in the range of 1-30°, in some embodiments in the range of 3°-7°, and yet other embodiments at 5°. As a point of reference, with tilted PV solar collection installations, the PV laminate 30 can be positioned so as to face or tilt generally southward (in northern hemisphere installations), including facings deviating from a true south direction. Given this typical installation orientation, then, the leading frame member 50 can thus be generally referred to as a south frame member, and the trailing frame member 52 referred to as a north frame member. In other embodiments, however, the frame 28 can be configured to maintain the PV laminate 30 in a generally parallel relationship relative to the flat surface S.

FIG. 1C provides an illustration of two PV modules coupled together in a ballasting state, in accordance with some embodiments. The tray 24 extends between the legs 42a, 42b. With this construction, the tray 24 serves to inhibit overt movement of both of the legs 42a, 42b (i.e., each of the legs 42a, 42b provides the engagement surface 32 described above, with tray 24 having corresponding stop surfaces 34 (FIG. 1A)). Further, at least a portion, and in some embodiments an entirety, of the tray 24 is positioned beneath or vertically under the PV laminate 30 and/or corresponding components of the framework 40 (e.g., the trailing frame member 52). With this arrangement, an open space 172 remains between the legs 42a, 42b, and is not otherwise occupied by the tray 24. The space 172 provides a convenient region or walkway when the PV module assembly 20 is provided as part of a PV module array. Conversely, the ballast tray 24 can be removed from the installation site (or not otherwise initially associated with the PV module 22). This represents another optional feature in accordance with the present disclosure whereby installers can selectively decide whether or not each individual PV module of an intended array does or does not require ballast. For example, relative to an array having a multiplicity of the PV modules 22, ballasting “adjustments” can be made with respect to each individual PV module 22. Trays 24 can be provided for some of the PV modules, and the ballast mass/weight contained thereby selected as desired; for others of the PV modules 22, the trays 24 are not provided.

Along these same lines, portions of an exemplary PV module array 190 is shown in FIG. 1D and includes first and second PV modules 22a, 22b mounted to one another in an end-to-end arrangement. In this regard, a first PV module 22a is provided as part of a PV module assembly 20a in accordance with the present disclosure, and thus includes the tray 24 (partially hidden in the view of FIG. 1D) removably associated with the frame 28 as previously described. Positioning of the tray 24 relative to the first PV module 22a (partially or entirely beneath the PV laminate 30) is such that the tray 24 does not obstruct coupling between the leg 42b of the first PV module 22a and the coupling element 44b of the second PV module 22b as shown. Further, a walkway 200 (referenced generally) between the PV modules 22a, 22b remains open (i.e., not obstructed by the tray 24), thereby allowing installation personnel to freely move along the array 190.

While FIGS. 1A-1D reflect two legs 42a, 42b, in other embodiments a greater or lesser number can be included. With respect to the one non-limiting example of FIG. 1A, the legs 42a, 42b are identical, defining mirror images upon final construction of the frame 28. However, in other embodiments may include coupling elements (such as legs 42a, 42b) that are not identical. Furthermore, although the description may refer to some elements as being on a first or second module, according to embodiments, each module in an array may have the described features. FIGS. 1A-1D illustrate one exemplary ballasted PV module system in which abrasion mitigation mechanisms may be implemented. However, other embodiments may include other PV module systems with chained module supports. For example, embodiments may also involve non-ballasted PV module assemblies with chained module supports, or any other chained PV module systems.

FIGS. 1E and 1F illustrate another embodiment in which the PV device is coupled with a base (e.g., frame) so that the angle of the PV device relative to the installation surface may be adjusted (e.g., one angle for shipping and a second inclined angle for use). In the embodiment illustrated in FIGS. 1E and 1F, a PV assembly 614 may include a PV module 618, a rear deflector 620 and a base 622. In the illustrated embodiment, the base 622 includes a main body 624, which may be made of, for example, thermally insulating foam, such as polystyrene, by DOW Chemical, or Noryl PPO (polyphenylene oxide) by GE Plastics, and a base cover 626. In one such embodiment, the main body 624 can be made of a closed cell foam, such as polystyrene, to help prevent absorption of water, which may degrade its thermal insulating properties. The cover 626 may provide an effective barrier to water diffusion into the upper surface of main body 624. However, the cover 626 may be useful to provide a moisture barrier along the lower surface 627 of main body 624 to help prevent such moisture diffusion.

The first, lower PV module end 628 is secured to base 622 by a module connector 630. The module connector 630 may be, for example, a one-piece, living hinge type of connector. The second, upper PV module end 642 is connected to the second, upper deflector end 644 by a coupler 646. According to one embodiment, one end of coupler 646 is secured to the second PV module end 642 by a nut, bolt and washer assembly while the other end is pivotally mounted to second deflector end 644 by a pivot, enabling a relative pivotal movement between the deflector 620 and coupler 646 when moving from relatively flat, shipping state to an inclined-use state.

The PV assembly 614 illustrated in FIG. 1E also includes side deflectors (e.g., a right-side deflector 682A and a left-side deflector (obscured from view in FIG. 1E)). In one embodiment, the side deflectors are mounted to the outside edges of the PV assemblies at the end of each row of a PV module array. Side deflectors may be used to prevent wind gusts from entering the array from the side, which in turn, can inhibit uplift on or sliding of the array.

In accordance with the embodiment illustrated in FIG. 1E, interengagement of adjacent PV assemblies may be through the use of coupling elements 602 and 604 formed in the main body 624 of each base 622 and/or in the cover 626 of each base 622. In accordance with embodiments described herein, the coupling elements 602 and 604 may be the same as, or similar to, the coupling elements described with reference to FIGS. 1A-1B (e.g., 42a-b and 44a-b). Thus, FIGS. 1E and 1F illustrate another exemplary embodiment in which an abrasion mitigation mechanism may be implemented. Other embodiments may include other variations, such as a module with an adjustable PV device angle (such as in FIGS. 1E and 1F), with a frame having legs (such as in FIG. 1A).

Returning to FIG. 1A, the framework 40 can assume a variety of forms appropriate for encasing the perimeter 38 of the PV laminate 30, as well as establishing the desired tilt angle θ (FIG. 1B). In some embodiments, the frame members 50-56 are separately formed and subsequently assembled to one another and the PV laminate 30 in a manner generating a unitary structure upon final construction. Alternatively, other manufacturing techniques and/or components can be employed such that the framework 40 reflected in FIG. 1A is in no way limiting.

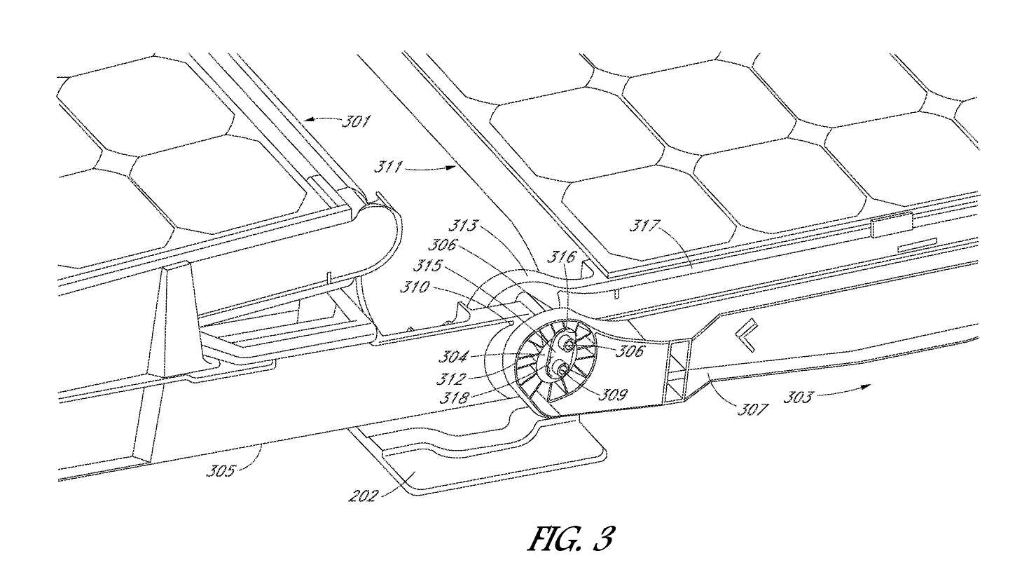

As mentioned above, the frame 28 includes coupling element(s) 42a, 42b extending from the framework 40. According to embodiments, the first coupling element(s) 42a, 42b of the photovoltaic module are adapted to releasably couple with second coupling element(s) 44a, 44b of a different photovoltaic module (not shown in FIG. 1A). For example, turning to FIG. 2, two PV modules are coupled via coupling elements 205, 207. Like the coupling elements 42a, 42b, 44a, 44b of FIG. 1A, the coupling elements 205, 207 of FIG. 2 are depicted as legs (also referred to herein as mounting legs). However, the coupling elements 205, 207 may also take other forms.

In the illustrated embodiment, the first coupling element 205 extends from and outwardly beyond the first end 213. The second coupling element 207 extends from and outwardly beyond the second end 215 of the module 203. The first coupling element 205 of a first module 201 has a first coupling interface 210 adapted to couple to a connector assembly for engagement with the second coupling element 207 of the photovoltaic module 203. The second coupling element 207 has a second coupling interface 212 adapted to couple to the connector assembly, wherein engagement of the first coupling element 205 of the photovoltaic module 201 with the second coupling element 207 of the different photovoltaic module 203 permits substantial planar movement of the second coupling element 207 of the photovoltaic module 203 independent of the photovoltaic module 201. Substantial planar movement is movement between two or more coupling elements of different modules coupled together in an array in a plane that is substantially parallel to the installation surface over which the PV modules are installed.

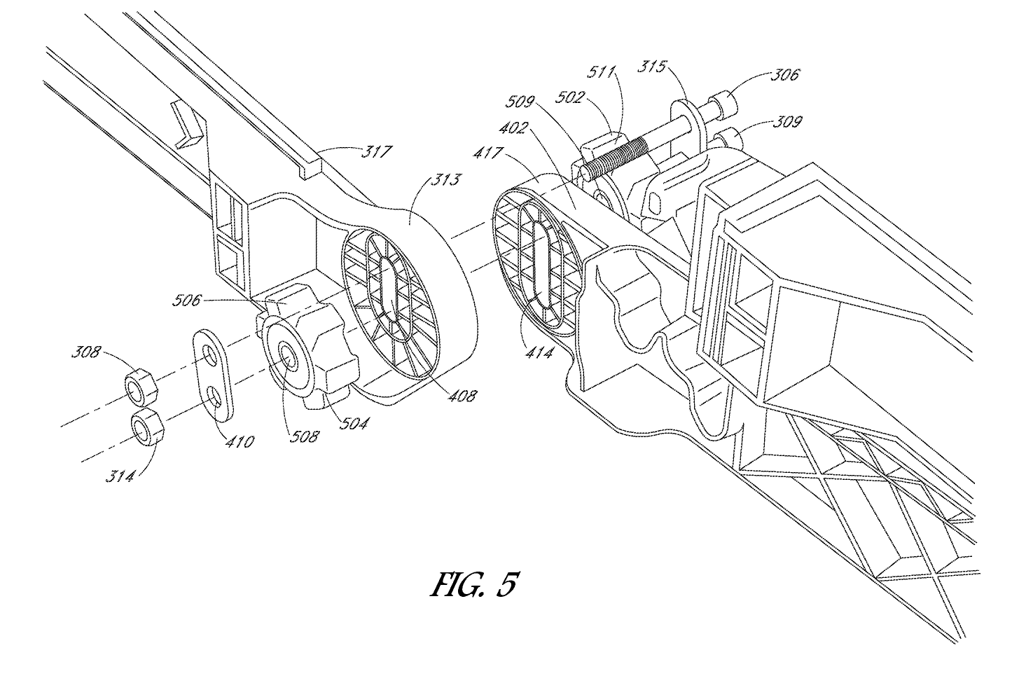

Referring again to FIG. 2, the connector assembly includes a first fastener 209. The first fastener 209 of FIG. 2 includes a first connector 206 and a second connector (obscured from view in FIG. 2 by the first interface 210). In one embodiment, and as illustrated in FIG. 2, the first connector 206 is a bolt. A bolt can be a fastening rod, pin, or screw, which may or may not be threaded to receive a nut, among other embodiments. The second connector is adapted for engagement with the first connector 206. For example, in an embodiment where the first connector 206 is a threaded bolt, the second connector may be a nut that engages the first connector 206 with a threaded hole. FIGS. 4 and 5 illustrate examples of second connectors (e.g., the nuts 308 and 314 of FIG. 4).

The first coupling interface 210 includes a first hole (hidden from view in FIG. 2 by the second coupling interface 212). The second coupling interface 212 of the second coupling element 207 of the different photovoltaic module 203 includes a second hole 204, enabling a lateral movement of the second coupling element 207 of the different photovoltaic module 203 relative to the photovoltaic module 201 when the fastener 209 is coupled with the first hole and the second hole 204. The first hole and the second hole 204 are sized to slidably receive a portion of the first connector 206. For example, in an embodiment where the first connector 206 is a bolt, the diameter or width of the bolt is smaller than a diameter or width of the first and second hole 204 to enable the connector 206 to slide in the first hole and the second hole 204 (as opposed to a bolt that fits tightly in the holes and/or has threaded engagement with the holes). Therefore, the first and second holes may be referred to as “oversized” holes relative to the first connector 206. According to one embodiment, the size of the holes is large enough to accommodate movement of the coupling element 207 (due to, e.g., thermal expansion and contraction of the PV module 203) without movement of the coupling element 205.

According to one embodiment, the first hole of the first coupling element 205 is disposed vertically offset from the second hole 204 in height with respect to the installation surface. For example, the first hole of the first coupling element 205 is vertically offset from the second hole 204 to the extent that the second coupling element 207 of the different photovoltaic module 203 is, in use, elevated relative to the first coupling element 205 of the photovoltaic module 201 while the first coupling element 205 of the photovoltaic module 201 rests on the installation surface. The second coupling element 207 could therefore be said to “hang” from the first coupling element 205, forming a “floating” connection between the first coupling element 205 and the second coupling element 207. The first hole and the second hole 204 may be any shape capable of slidably receiving a portion of the first connector 206, such as round holes, square holes, slots, slots with one rounded end and one flat end, or any other shape capable of slidably receiving a portion of the first connector 206. In one embodiment with a slot having a flat bottom end, the flat bottom end accommodates movement between the coupling elements by, in part, inhibiting the bolt from resting in the bottom of the slot.

Thus, when the photovoltaic module 201 and the different photovoltaic are mounted adjacent to each other (e.g., when the modules are in use), engagement of the first connector 206 and second connector may provide a mounted state that enables the lateral movement of the second coupling element 207 of the different photovoltaic module 203 relative to the photovoltaic module 201. For example, the mounted state may enable movement in an uphill slope direction and a downhill slope direction opposite of the uphill slope direction.

The first coupling element 205 of the photovoltaic module 201 may also couple with a connector to anchor the photovoltaic module to the installation surface. For example, in the illustrated embodiment, a pad 202 is a connector adapted to frictionally engage the first coupling element 205 of the first photovoltaic module 201 to an installation surface such that, in use, a first friction force between a surface of the pad 202 and the installation surface is greater than a second friction force present in a connection formed between the first coupling element 205 and the second coupling element 207. The pad 202 may be attached to (or a part of) the first coupling element 205, or the pad 202 may be a separate component from the first coupling element 205 that contacts the first coupling element 205 upon installation. In one such embodiment, installation would involve placing the pad 202 on the installation surface, and resting the coupling element 205 over the pad 202. The pad 202 may be formed from a material that creates a relatively large friction force between the pad 202 and the installation surface, and between the pad 202 and the first coupling element 205. For example, the pad may be formed from rubber (e.g., EPDM or another rubber), or another high friction material. According to one embodiment, the high friction force created by the pad 202 ensures friction in the coupling interface between the “floating” connection between the first coupling element 205 and the second coupling element 207 is overcome during thermal expansion and contraction of the modules.

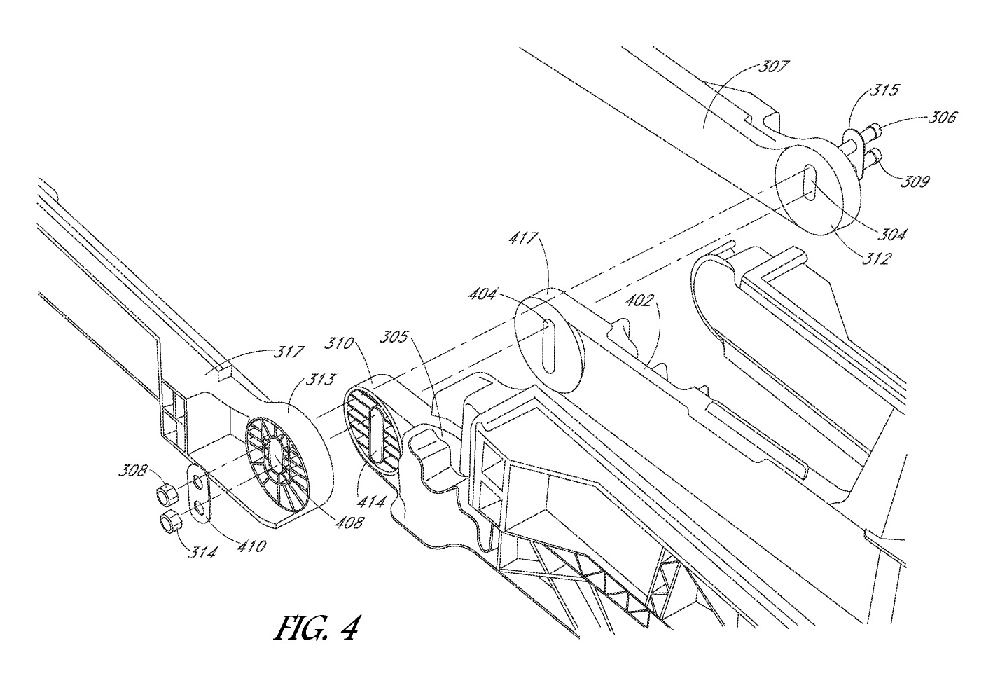

Thus, FIG. 2 illustrates a single-bolt connector assembly configured to couple PV modules together, in accordance with embodiments of the present disclosure. Although FIG. 2 illustrates two PV modules 201, 203, other numbers of PV modules may be coupled at a given junction in an array depending on, for example, the PV modules' location in the array and features of the installation surface. For example, FIG. 3 illustrates three PV modules 301, 303, 311 coupled via coupling elements 305, 307, 313. FIG. 3 illustrates PV modules as installed or mounted on an installation surface, and therefore some of the details of the PV modules and connector assembly are obscured from view. Furthermore, some elements of the PV module 303 (e.g., the laminate) are not shown in FIG. 3 in order to more clearly depict the coupling elements. However, FIGS. 4 and 5 are exploded perspective views of PV module assemblies, which depict some of the elements that are obscured from view in FIG. 3.

Referring to FIG. 3, a first coupling element 305 of a first module 301 has a first coupling interface 310 adapted to couple to a connector assembly for engagement with a second coupling element 307 of a different photovoltaic module 303. The second coupling element 307 has a second coupling interface 312 adapted to couple to the connector assembly. Also depicted in FIG. 3, is a third module 311, which includes a third coupling element 317 having a third interface 313. The third coupling element may be similar to the second coupling element 307, however, in the illustrated embodiment, the third coupling element 317 is oriented such that the third coupling element 317 mirrors the second coupling element 307 (e.g., the “outer” face of the third coupling element 317 faces the “outer” face of the second coupling element 307). Other embodiments (including the embodiment illustrated in FIG. 4, which is discussed below) may include a fourth PV module.

In contrast to FIG. 2, which illustrated a single-bolt connector assembly, FIG. 3 depicts an embodiment with a connector assembly having multiple fasteners 316 and 318. The first fastener 318 includes a first connector 309 (note that only the end of the first connector 309 is visible in FIG. 3), and a second connector (obscured from view in FIG. 3) adapted for engagement with the first connector 309. Similarly, the second fastener 316 includes a third connector 306 and a fourth connector (obscured from view in FIG. 3) adapted for engagement with the third connector 306. In one such embodiment, the first and third connectors 306, 309 are male fasteners (e.g., bolts), and the second and fourth connectors are female fasteners (e.g., nuts). In the illustrated embodiment, the first connector 309 is a “lower” or “bottom” bolt, and the third connector 306 is an “upper” or “top” bolt.

Holes in the coupling interfaces are sized to receive the connectors 306, 309. For example, a first hole of the first interface 310 (obscured from view in FIG. 3), a second hole 204 (partially obscured from view in FIG. 3) of the second interface, and a third hole of a third interface 313 (also obscured from view in FIG. 3) are sized to slidably receive a portion of the first connector 309. However, unlike the embodiment illustrated in FIG. 2, the third connector 306 is adapted to pass over and slide on a top surface of the first coupling element 305 (e.g., instead of passing through the first hole in the first coupling element 305). Therefore, in one such embodiment, the second coupling element hangs from the first element via the third connector 306.

The connector assembly further includes a fifth connector 315 and a sixth connector (obscured from view in FIG. 3). The sixth connector may be similar to the fifth connector 315, but located, for example, on the other side of a coupling element of another PV module to which the PV module 303 is to be coupled. For example, in FIG. 3, the sixth connector is located on the far face of the interface 313. The fifth and sixth connectors are adapted for engagement with the first and third connectors 309, 306 such that the fifth and sixth connectors orient the first and third connectors 309, 306 adjacent to each other to provide a mounted state. For example, in the embodiments illustrated in FIG. 4, the fifth connector 304 and sixth connector 410 are plates (e.g., washers). In one such embodiment, each of the plates 304, 410 has at least two holes, wherein one of the at least two holes is adapted to receive a portion of the first connector 309 and another one of the at least two holes adapted to receive a portion of the third connector 306 to together slidably mount the second coupling element 307 on the first coupling element 305. The mounted state enables lateral movement of the second coupling element 312 of the different photovoltaic module 303 relative to the photovoltaic module 301 upon installation of the photovoltaic module 301 and the different photovoltaic module 303 adjacent to each other.

As indicated above, FIG. 4 is an exploded view of a PV module assembly, which more clearly illustrates some features obscured from view in FIG. 3. FIG. 4 illustrates an embodiment similar to the PV module assembly of FIG. 3, however, FIG. 4 further illustrates a fourth coupling element 402 configured to couple a fourth PV module (not shown) to the array via a fourth coupling interface 417.

As can be seen more clearly in FIG. 4, according to one embodiment, each of the coupling elements have holes sized to slidably receive the lower bolt 309. The upper bolt 306 passes through the hole 304 of the interface 312 and through the hole 408 of the interface 313. However, instead of passing through the holes 404 and 414, the upper bolt 306 passes over a top surface of the coupling elements 402 and 305, as indicated by the directional dotted lines. As mentioned above, the coupling elements 307 and 317 could therefore be referred to as hanging from the coupling elements 402 and 305. Thus, in the illustrated embodiment, the holes 304, 404, 414, and 408 at least partially overlap, but the holes 404 and 414 are vertically offset from the holes 304 and 408. The upper bolt 306, when thus installed, is configured to slide on the top surface of the coupling elements 402 and 305 to enable planar movement of the coupling elements 307 and 317 relative the coupling elements 305 and 402 (e.g., in a direction perpendicular to the bolts and in a plane parallel to the surface of the coupling interfaces 310 and 317 over which the bolts slide). Note that although all the holes 304, 404, 414, and 408 are illustrated in FIG. 4 as being the same size and shape, the holes may have different shapes and/or sizes. For example, in one embodiment, the holes through which only a single bolt is going to pass (e.g., the holes 404 and 414) may be smaller than the holes through which two bolts are going to pass (e.g., the holes 304 and 408). In one such embodiment, the larger holes are vertical slots (e.g., vertically elongated openings), and the smaller holes are another shape (e.g., round holes, half-circle holes, or holes having another shape).

The degree to which the coupling elements 307 and 317 can move relative to the coupling elements 305 and 402 is limited in part by the size of the holes 304, 404, 414, and 408. In the illustrated embodiment, the extent of movement of the coupling elements 305 and 402 is also limited by additional connectors 410, 315, 308, and 314. As indicated above, the additional connectors 410 and 315 couple with and align the bolts 306 and 309 relative to each other (e.g., vertically so that the bolt 306 is directly aligned over the bolt 309). According to one embodiment, the additional connectors 410 and 315 may be plates (e.g., metal plates or plates formed from another suitable material) with holes through which the bolts 306 and 309 pass. The connectors 308, and 314 are also configured to couple with the bolts 306 and 309. In the illustrated embodiment, the connectors 308, and 314 are nuts that engage the bolts 306 and 309 via complementary threads on the ends of the bolts 306 and 309 and in the hole of the nuts 308, and 314.

FIG. 5 is an exploded view of another embodiment including a two-bolt connector assembly. FIG. 5 illustrates an embodiment similar to the PV module assembly of FIGS. 3 and 4, however, FIG. 5 illustrates an example of two coupling elements 317 and 402 for coupling two PV modules together (as opposed to the three elements illustrated in FIG. 3, and four coupling elements illustrated in FIG. 4). Additionally, FIG. 5 illustrates an embodiment with additional connectors 502, 504. The additional connectors 502, 504 are adapted to couple with the bolts 306, 309 between the connectors 315, 410 and the coupling interfaces 417, 313. For example, the connectors 502, 504 include holes 509, 508, to slidably receive the bolt 309. In the illustrated embodiment, the lower bolt 309 passes through holes 509, 508. The connectors 502 and 504 further include at least one notch into which the bolt may be slidably received. For example, the top bolt 306 passes through and rests in notches 511 and 506 of the connectors 502 and 504, such that the top bolt 306 can slide in the notches 511 and 506. The connectors 502 and 504 thus limit the movement of, and assist in alignment of, the bolts 306 and 309. The connectors may be especially beneficial when coupling only two modules, as illustrated in FIG. 5. For example, referring again to FIG. 4, the coupling elements 402 and 305 are disposed (e.g., “sandwiched”) between the coupling elements 317 and 307. Thus, in one such embodiment, the coupling elements 317 and 307 may act to align and limit the movement of the bolts 306 and 309 to be within the desired range. However, in a two module embodiment such as in FIG. 5, the coupling element 402 over which the bolt 306 passes is not surrounded on both sides by coupling elements. Therefore, the notched connectors 502 and 504 may beneficially align and limit the range of motion of the top bolt 306 over the coupling element 402. Although FIG. 5 illustrates two notched connectors 502 and 504, in another embodiment, a single notched connector 502 may be used. In other embodiments, such as the embodiment depicted in FIG. 4, no notched connectors are used.

Thus, mitigation techniques for PV module installation surface abrasion are described herein. As discussed above, embodiments of the present disclosure allow each PV module to expand and contract relative to an adjacent PV module without exerting a significant force on the adjacent module. Therefore, embodiments may prevent significant movement of the PV modules (e.g., PV modules in a ballasted PV array) on the installation surface, and prevent abrasion and wear of the installation surface due to such movement. Additionally, embodiments may reduce stress on the parts of both ballasted and non-ballasted PV arrays due to thermal expansion and contraction, and therefore increase the longevity of the parts of the PV array.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A photovoltaic module comprising:
a photovoltaic laminate; and
a frame coupled to the photovoltaic laminate, the frame including a first coupling element on a first end and a second coupling element on a second end opposite the first end of the frame,
wherein the first coupling element of the photovoltaic module is adapted to releasably attach the photovoltaic module to an installation surface and releasably couple with a second coupling element of a different photovoltaic module, the first coupling element having a first coupling interface adapted to couple to a connector assembly for engagement with the second coupling element of the different photovoltaic module, and
wherein the second coupling element of the photovoltaic module has a second coupling interface adapted to couple to the connector assembly, wherein engagement of the first coupling element of the photovoltaic module with the second coupling element of the different photovoltaic module permits substantial planar movement of the second coupling element of the different photovoltaic module independent of the photovoltaic module.

2. The photovoltaic module of claim 1, wherein:
the connector assembly includes a first fastener;
the first coupling interface of the first coupling element of the photovoltaic module comprises a first hole; and
a second coupling interface of the second coupling element of the different photovoltaic module comprises a second hole, enabling a lateral movement of the second coupling element of the different photovoltaic module relative to the first coupling element of the photovoltaic module when the fastener is coupled with the first and second holes.

3. The photovoltaic module of claim 2, wherein the first fastener includes:
a first connector, wherein the first hole and the second hole are sized to slidably receive a portion of the first connector; and
a second connector adapted for engagement with the first connector,
wherein engagement of the first and second connectors, in use, provides a mounted state that enables the lateral movement of the second coupling element of the different photovoltaic module relative to the photovoltaic module in an uphill slope direction and a downhill slope direction opposite of the uphill slope direction upon installation of the photovoltaic module and the different photovoltaic module adjacent to each other.

4. The photovoltaic module of claim 2, wherein:
the first fastener comprises:
a first connector, wherein the first hole and the second hole are sized to slidably receive a portion of the first connector, and
a second connector adapted for engagement with the first connector;
the connector assembly further comprises a second fastener, wherein the second fastener comprises:
a third connector adapted to pass over and slide on a top surface of the first coupling element, wherein the second hole is sized to slidably receive a portion of the third connector, and
a fourth connector adapted for engagement with the third connector;
wherein the connector assembly further comprises a fifth connector adapted for engagement with the first and third connectors such that the fifth connector orients the first and third connectors adjacent to each other to provide a mounted state; and
the connector assembly further comprises a sixth connector adapted for engagement with the first and third connectors such that the sixth connector orients the first and third connectors adjacent to each other to provide the mounted state that enables the lateral movement of the second coupling element of the different photovoltaic module relative to the photovoltaic module in an uphill slope direction and a downhill slope direction opposite of the uphill slope direction upon installation of the photovoltaic module and the different photovoltaic module adjacent to each other.

5. The photovoltaic module of claim 2, wherein the first hole is disposed vertically offset from the second hole in height with respect to the installation surface to the extent that the second coupling element of the different photovoltaic module is, in use, elevated relative to the first coupling element of the photovoltaic module while the first coupling element of the photovoltaic module rests on the installation surface.

6. The photovoltaic module of claim 1, wherein the first coupling element of the photovoltaic module is adapted to receive a connector adapted to couple to the first coupling element of the photovoltaic module to anchor the photovoltaic module to the installation surface.

7. A photovoltaic system comprising:
first and second photovoltaic modules each including a first coupling element on a first end and a second coupling element on a second end opposite of the first end; and
a connector assembly including a fastener adapted to engage the first coupling element of the first photovoltaic module with the second coupling element of the second photovoltaic module wherein the fastener is configured to provide an engagement state that enables movement of the second coupling element of the second photovoltaic module independent of the first photovoltaic module.

8. The photovoltaic system of claim 7,
wherein the engagement state enables the movement of the second coupling element of the second photovoltaic module independent of the first photovoltaic module upon installation of the first and second photovoltaic modules on an installation surface,
wherein the first coupling element extends from and outwardly beyond the first end and the second coupling element extends from and outwardly beyond the second end, and
wherein the first coupling element of the first photovoltaic module has a first hole and the second coupling element of the second photovoltaic module has a second hole, wherein the fastener includes:
a first connector, wherein the first hole and the second hole are sized to slidably receive a portion of the first connector, and
a second connector adapted for engagement with the first connector.

9. The photovoltaic system of claim 8, further comprising:
a connector adapted to couple to the first coupling element of the first photovoltaic module to anchor the first photovoltaic module to the installation surface.

10. The photovoltaic system of claim 9, wherein the connecter is a pad that is adapted to frictionally engage the first coupling element of the first photovoltaic module to the installation surface such that, in use, a first friction force between a surface of the connector and the installation surface is greater than a second friction force present in a connection formed between the first coupling element of the first photovoltaic module and the second coupling element of the second photovoltaic module by using the first and second connectors of the connector assembly.

11. The photovoltaic system of claim 8, wherein the first hole is disposed vertically offset from the second hole in height with respect to the installation surface to the extent that the second coupling element of the second photovoltaic module is, in use, elevated relative to the first coupling element of the first photovoltaic module while the first coupling element of the first photovoltaic module rests on the installation surface.

12. The photovoltaic system of claim 11, wherein the first hole has a first diameter and the second hole has a second diameter such that the first diameter of the first hole and the second diameter of the second hole are sized to enable the lateral movement of the second coupling element of the second photovoltaic module relative to the first coupling element of the first photovoltaic module in an uphill slope direction and a downhill slope direction opposite of the uphill slope direction upon the installation of the first and second photovoltaic modules adjacent to each other.

13. The photovoltaic system of claim 7, wherein:
the first coupling element of the first photovoltaic module has a first slot and the second coupling element of the second photovoltaic module has a second slot,
wherein the fastener includes:
a first connector, wherein the first slot and the second slot are sized to slidably receive a portion of the first connector, and
a second connector adapted for engagement with the first connector,
wherein the connector assembly further comprises another fastener adapted to movably engage the first coupling element of the first photovoltaic module with the second coupling element of the second photovoltaic module, the another fastener including:
a third connector adapted to pass over and slide on a top surface of the first coupling element, wherein the second slot is sized to slidably receive a portion of the third connector, and
a fourth connector adapted for engagement with the third connector, wherein the connector assembly further comprises:
a fifth connector adapted for engagement with the first and third connectors such that the fifth connector orients the first and third connectors adjacent to each other to provide a mounted state; and
the connector assembly further comprises a sixth connector adapted for engagement with the first and third connectors such that the sixth connector orients the first and third connectors adjacent to each other to provide the mounted state that enables the lateral movement of the second coupling element of the second photovoltaic module relative to the first coupling element of the first photovoltaic module in an uphill slope direction and a downhill slope direction opposite of the uphill slope direction upon the installation of the first and second photovoltaic modules adjacent to each other.

14. The photovoltaic system of claim 13, wherein the first and third connectors are a male fastener, the second and fourth connectors are a female fastener, and the fifth and sixth connectors are plates each of which having at least two holes wherein one of the at least two holes is adapted to receive a portion of the first connector and another one of the at least two holes adapted to receive a portion of the third connector to together slidably mount the second coupling element on the first coupling element.

15. The photovoltaic system of claim 13, further comprising:
a connector adapted to couple to the first coupling element of the first photovoltaic module to anchor the first photovoltaic module to an installation surface.

16. The photovoltaic system of claim 15, wherein the connecter is a pad that is adapted to frictionally engage the first coupling element of the first photovoltaic module to the installation surface such that, in use, a first friction force between a surface of the connector and the installation surface is greater than a second friction force present in a connection formed between the first coupling element of the first photovoltaic module and the second coupling element of the second photovoltaic modules by using the first, second, third, and fourth connectors of the connector assembly.

17. The photovoltaic system of claim 13, wherein the first and second slots are sized such that the second slot only partially overlaps with the first slot in height with respect to an installation surface to the extent that the second coupling element of the second photovoltaic module is, in use, elevated relative to the first coupling element of the first photovoltaic module while the first coupling element of the first photovoltaic modules rests on the installation surface.

18. The photovoltaic system of claim 17, wherein the first slot has a first diameter and the second slot has a second diameter such that the first diameter of the first slot and the second diameter of the second slot are sized to enable the planar movement of the first photovoltaic module relative to the second photovoltaic module in an uphill slope direction and a downhill slope direction opposite of the uphill slope direction upon the installation of the first and second photovoltaic modules adjacent to each other.

19. A photovoltaic system comprising:
a photovoltaic module comprising a photovoltaic laminate and a frame coupled with the photovoltaic laminate,
wherein the frame comprises a first leg at a first end of the frame and a second leg at a second end of the frame opposite to the first end,
wherein the first leg is configured to rest on an installation surface, creating friction between the first leg and the installation surface, and
wherein the second leg comprises a hole that at least partially overlaps a hole in a first leg of another photovoltaic module when the photovoltaic module is adjacent to and coupled with the other photovoltaic module on the installation surface; and
a bolt sized to pass through the hole in the second leg of the photovoltaic module and the hole in the first leg of the other photovoltaic module to slidably couple the second leg of the photovoltaic module with the first leg of the other photovoltaic module, creating less friction between the second leg and the first leg of the other photovoltaic module than between the first leg and the installation surface.

20. The photovoltaic system of claim 19, further comprising:
a friction pad configured to be disposed between the first leg and the installation surface, preventing substantial planar movement of the first end of the frame relative to the installation surface.
